(19) United States
(12) Patent Application Publication
(10) Pub. No.: US 2016/0276042 A1
(43) Pub. Date: Sep. 22, 2016

(54) One Time Programmable Memory

(71) Applicant: Microchip Technology Incorporated, Chandler, AZ (US)

(72) Inventors: Rodney Pesavento, Chandler, AZ (US); Michael Simmons, Chandler, AZ (US)

(73) Assignee: Microchip Technology Incorporated, Chandler, AZ (US)

(21) Appl. No.: 15/072,759

(22) Filed: Mar. 17, 2016

Related U.S. Application Data
(60) Provisional application No. 62/136,061, filed on Mar. 20, 2015.

(51) Int. Cl. G11C 17/16; G11C 29/00

(52) U.S. Cl. CPC G11C 17/16; G11C 29/76

(57) ABSTRACT

Systems and method for controlling the programming of a one-time programmable (OTP) memory are disclosed. The systems and methods include an OTP memory array comprising an array organized in lines of n+1 bit, wherein n is an integer number designating a word size of the OTP memory, wherein the additional bit indicates whether a memory line is stored in an inverted or non-inverted fashion, encoding logic configured determine whether a word is to be stored inverted or non-inverted, and decoding logic configured to decode a stored word and controlled by the additional bit indicating whether a word has been stored inverted or non-inverted.

### CROSS-REFERENCE To RELATED APPLICATIONS

This application claims priority to commonly owned U.S. Provisional Patent Application No. 62/136,061 filed Mar. 20, 2015; which is hereby incorporated by reference herein for all purposes.

### TECHNICAL FIELD

The present disclosure relates to one-time programmable memory, and in particular to a method and system for the minimization of programming such memories.

### BACKGROUND

As compared to Flash technology, the programming time of One Time Programmable (OTP) memories can be longer by an order of magnitude or so. In addition, the programming time depends on the number of bits to be programmed to a particular programmed state (typically ‘1’). In many OTP implementations, programming to the opposite erased state (typically ‘O’) need not be performed, because all bits in the OTP memory are in their erased state when they have completed fabrication. However, due to the fact that we cannot predict the bias (number of ‘O’ vs ‘1’) in the OTP contents, we are still stuck with a maximum programming time value that assumes all bits are programmed.

### SUMMARY

According to various embodiments, OTP programming time can be minimized by algorithmically selecting between inverted and non-inverted programming Words.

According to various embodiments, systems and method for controlling the programming of a one-time programmable (OTP) memory are disclosed. The systems and methods include an OTP memory array comprising an array organized in lines of n+1 bit, wherein n is an integer number designating a word size of the OTP memory, wherein the additional bit indicates whether a memory line is stored in an inverted or non-inverted fashion, encoding logic configured determine whether a word is to be stored inverted or non-inverted, and decoding logic configured to decode a stored word and controlled by the additional bit indicating whether a word has been stored inverted or non-inverted.

In some embodiments, the systems and methods include a circuit arrangement for programming a one-time programmable (OTP) memory. The circuit arrangement may include an OTP memory array comprising an array organized in lines of n+1 bit, wherein n is an integer number designating a word size of the OTP memory, wherein the additional bit indicates whether a memory line is stored in an inverted or non-inverted fashion; encoding logic configured determine whether a word is to be stored inverted or non-inverted; and decoding logic configured to decode a stored word and controlled by the additional bit indicating whether a word has been stored inverted or non-inverted. In some embodiments, “n” may be equal to thirty-two. In some embodiments, the OTP memory may include address and control inputs for reading and writing a word.

In some embodiments, the encoding logic may also store a word inverted if the number of bit having a value of ‘1’ is greater than n/2 and setting the additional bit in that word and if not then the encoding logic stores a word non-inverted without setting the additional bit. In such embodiments, the encoding logic may include an inverter for inverting a word to be stored in the OTP memory, a multiplexer receiving the word and the inverted word, and a counter configured to count the number of logic ‘1’ in the word and operable to control the multiplexer to select the inverted word if the number of logic ‘1’ in the word is greater than n/2 and otherwise select the word for storage in the OTP memory.

In some embodiments, the decoding logic may include an inverter configured to invert a stored n-bit word and a multiplexer receiving the stored word and the inverted word, wherein the multiplexer is controlled by the additional bit.

In some embodiments, the encoding logic may store a word inverted if the number of bit having a value of ‘1’ is greater than or equal to n/2 and setting the additional bit in that word and if not then the encoding logic stores a word non-inverted without setting the additional bit.

In alternative embodiments, the encoding logic may store a word inverted if the number of bit having a value of ‘1’ is greater than an inversion threshold and setting the additional bit in that word and if not then the encoding logic stores a word non-inverted without setting the additional bit.

In some embodiments, the systems and methods may include a method for programming a one-time programmable (OTP) memory. The method may include storing a data word in an OTP memory array comprising an array organized in lines of n+1 bit, wherein n is an integer number designating the data word size of the OTP memory, wherein the additional bit indicates whether a memory line is stored in an inverted or non-inverted fashion; determining whether a word is to be stored inverted or non-inverted; and decoding a stored word and controlled by the additional bit indicating whether a word has been stored inverted or non-inverted.

In some embodiments, storing the data word inverted may include storing the data word inverted if the number of bit having a value of ‘1’ is greater than n/2 and setting the additional bit in that word and if not then the encoding logic stores a word non-inverted without setting the additional bit.

In such embodiments, storing the data word may include storing the data word via encoding logic, wherein the encoding logic comprises an inverter for inverting a word to be stored in the OTP memory, a multiplexer receiving the word and the inverted word, and a counter configured to count the number of logic ‘1’ in the word and operable to control the multiplexer to select the inverted word if the number of logic ‘1’ in the word is greater than n/2 and otherwise select the word for storage in the OTP memory.

In some embodiments, decoding the stored word may include decoding the stored word via decoding logic, and wherein the decoding logic comprises an inverter configured to invert a stored n-bit word and a multiplexer receiving the stored word and the inverted word, wherein the multiplexer is controlled by the additional bit.

In some embodiments, the systems and methods may include a computer-implemented method for executing program instructions stored on non-transitory computer-readable media by a processor, wherein the instructions when executed by the processor perform the steps including storing a data word in an OTP memory array comprising an array organized in lines of n+1 bit, wherein n is an integer number designating the data word size of the OTP memory, wherein the additional bit indicates whether a memory line is stored in an inverted or non-inverted fashion; determining whether a word is to be stored inverted or non-inverted; and decoding a stored word and controlled by the additional bit indicating whether a word has been stored inverted or non-inverted.

### BRIEF DESCRIPTION OF THE DRAWINGS

FIG. 1 illustrates an example programming scheme for determining whether to invert the read data to produce original program data, in accordance with certain embodiments of the present disclosure; and

FIG. 2 illustrates an example table of programming values for programming a scheme for programming a one-time programmable memory, in accordance with certain embodiments of the present disclosure.

### DETAILED DESCRIPTION

According to various embodiments, OTP programming time can be minimized by algorithmically selecting between inverted and non-inverted programming Words. In order to put a maximum value to the programming time for the entire array, it is possible to introduce a limiting of the number of bits being programmed to ‘1’, and therefore a limiting of the total programming time. This is done at the cost of adding one extra OTP bit for each n-bit word (where n bits represents the read/write width of the OTP array). For example, a 32-bit wide OTP array would be updated to be 33 bits wide.

To do this, the extra bit for each word in the OTP array is used to determine whether the corresponding word is an inverted or non-inverted representation of the desired value. When this word is written, the OTP controller (or in this case logic outside the OTP controller) counts the number of ‘1’s in the data to be written. If it is greater than n/2 (i.e., 16 bits for a 32-bit wide OTP array), then the data is inverted before being written into the array, and the (n+1) bit (hereafter called the “INV” bit) is written as ‘1’. If the number of ‘1’s is less than n/2, then the INV bit is not programmed (i.e., written as ‘O’).

When any word is written out of the array, the INV bit is read as part of the word, and used to determine whether to invert or not invert the read data to produce the original data that was to be programmed into the array.

Thus, the various embodiments, make use of bit wide programming and odd size OTP memory configurations to implement.

For example, for Novocell OTP arrays, the total programming time for a 32-bit word depends on the number of bits being programmed to ‘1 ’, and is a typical number, as programming of each bit is self-timed within the array. In addition, since the OTP array is manufactured to have an un-programmed state of ‘0’ out of the fab, it is only necessary to program ‘1’ bits-programming of ‘0’ bits is not necessary and such an operation is effectively skipped within the OTP array. This leads to the situation where the total programming time for an array must be given with a specified “bias” (i.e., how many bits in the array are being programmed to ‘1 ’, and how many bits are programmed to ‘0’).

In order to put a maximum value to the programming time for the entire array, it is possible to introduce a limiting of the number of bits being programmed to ‘1’, and therefore a limiting of the total programming time. According to various embodiments, this can be done at the cost of adding one extra OTP bit for each n-bit word (where n bits represents the read/write width of the OTP array). For example, a 32-bit wide OTP array would be updated to be 33 bits wide.

To do this, the extra bit for each word in the OTP array is used to determine whether the corresponding word is an inverted or non-inverted representation of the desired value. When this word is written, the OTP controller (or in this case logic outside the OTP controller) counts the number of ‘1’s in the data to be written. If it is greater than n/2 (i.e., 16 bits for a 32-bit wide OTP array), then the data is inverted before being written into the array, and the (n+1) bit (hereafter called the “INV” bit) is written as ‘1’. If the number of ‘1’s is less than n/2, then the INV bit is not programmed (i.e., written as ‘O’).

Although it is also possible to use the opposite polarity for the INV bit (i.e., INV=1 indicates that the corresponding word is not inverted), in some configurations for any n-bit binary word, the number of words that need to be inverted under this scheme is less than 50%. If the 1's count is compared using a less than n/2 function (versus greater than n/2, as described above), then the opposite polarity (i.e., INV=0 to indicate that the programming word is inverted) would result in the least number of overall programmed bits.

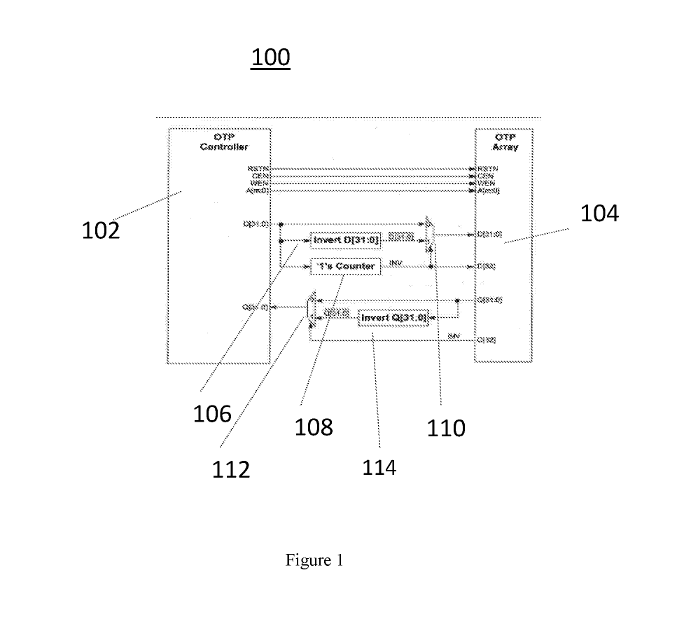

FIG. 1 illustrates an example programming scheme 100 for determining whether to invert the read data to produce original program data, in accordance with certain embodiments of the present disclosure. When any word is written out of the array, the INV bit is read as part of the word, and used to determine whether to invert or not invert the read data to produce the original data that was to be programmed into the array.

In some embodiments of scheme 100, it may not be necessary to count the entire n-bit word to determine the number of ‘1’s, as we only need to determine whether the number is greater than, equal to or less than n/2. To do this, it would be easier to logically OR pairs of bits and then determine if that count is greater than n/4.

As an example for a 32-bit OTP array, a system could OR bits 32 and 31, bits 30 and 29, . . . , bits 1 and 0, and then count the number of ‘1’s in the resulting 16-bit binary number to determine if it is greater than 8. If it is greater than 8, then we would invert the 32-bit word and program INV to ‘1’. otherwise, we would not invert the word, and would leave INV un-programmed.

In some embodiments, scheme 100 may include an OTP controller 102 communicatively coupled to an OTP array 104. OTP controller 102 may be any appropriate OTP controller such as those found in the Microchip PIC series. OTP array 104 may be any appropriate OTP array such as those found in the Microchip PIC series.

In some embodiments, OTP controller 102 may be communicatively coupled to OTP array 104 through one or more control signals. The number and type of control signals may vary according to the particular configuration of scheme 100. For example, OTP controller 102 may be communicatively coupled to OTP array 104 through a terminal resent (e.g., “RSTN”) signal, a command enable (e.g., “CEN”) signal, secondary enable (e.g., “WEN”) signal, and/or a plurality of address signals (e.g., “A[m:0]. OTP controller 102 may also be communicatively coupled to OTP array 104 through one or more data signals (e.g., “D[31:0],” which would illustrate a 32-bit data bus), as well as one or more secondary or return data signals (e.g., “Q[31:0],” which would illustrate a 32-bit data bus).

In some embodiments, the communicative coupling between OTP controller 102 and OTP array 104 may include a plurality of additional components as part of the data transfer. For example, scheme 100 may also include inverter 106, ones counter 108, multiplexor 110, inverter 112, and multiplexor 114. In some embodiments, the data that OTP controller 102 sends through the plurality of data signals may be multiplexed (via multiplexor 110) with an inversion of that same data. That data will have been inverted by inverter 106. The selection of which signal to multiplex at multiplexor 108 may be provided by ones counter 108. Ones counter 108 may be any appropriate circuitry operable to provide a count of the number of “1s” that are stored in the word size being written to OTP array 104 by OTP controller 102. Ones counter 108 may be operable to calculate this number and use it to determine whether the original data or the inverted data is to be written to OTP array 104. In addition, ones counter 108 may output the last logic “1” to be written as the extra bit in each stored word at OTP array 104

In some embodiments, scheme 100 may also include inverter 114 and multiplexor 112. In some embodiments, the data that OTP array 104 send through the plurality of return data signals (e.g., for a read) may be multiplexed (via multiplexor 112) with an inversion of that same data, as provided by inverter 114. In addition, multiplexor 112 may be switched by a signal from OTP array 104, wherein that signal may be the last, extra bit appended to the end of each word stored in OTP array 104.

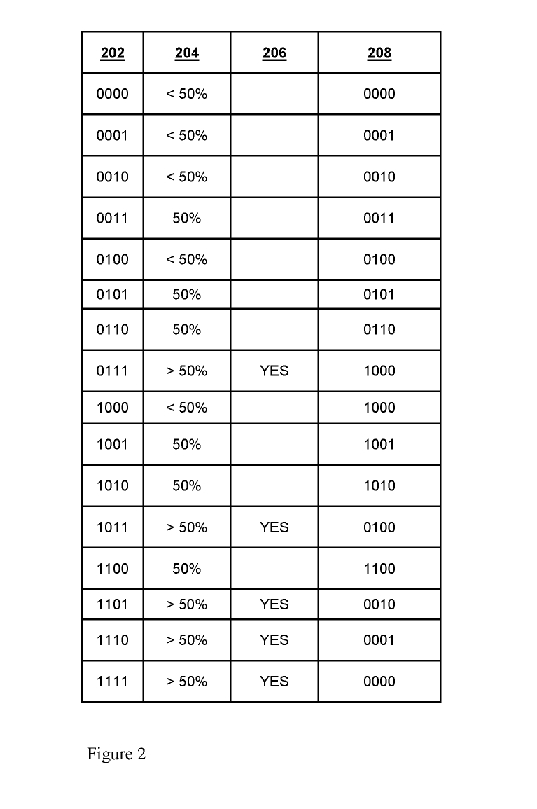

FIG. 2 illustrates an example table of programming values 200 for programming a scheme 100 for programming a one-time programmable memory, in accordance with certain embodiments of the present disclosure. Table of programming values 200 is provided as an aid in understanding the present disclosure and should not be understood as limiting the present disclosure.

In some embodiments, table 200 may include data column 202, zero bias column 204, inversion indication column 206, and programmed value column 208. Data column 202 includes each potential data for the data value to be programmed according to scheme 100. In the example, data range column 202 indicates only a four-bit range for ease of illustration. More, fewer, and/or different values may be present within any particular configuration without departing from the scope of the present disclosure.

Zero bias column 204 may be used to indicate the percentage of data values at the particular data are zero. Although any number of indication schemes may be used, in the example table 200, zero bias column 204 indicates whether the particular data has less than fifty percent, exactly fifty percent, or greater than fifty percent zero. Inversion indication column 206 may then indicate whether to invert the data at the particular data based at least on whether the zero bias at that data location is over a particular threshold. For example, if the zero bias is greater than fifty percent, then invert the data. Inversion indication column 206 may include a data value associated with a particular data value indicating whether to invert the data. For example, the table may include a “YES” if the data is to be inverted. In other configurations, inversion indication column 206 may include a logical zero for “do not invert” and a logical one for “do invert” or vice versa. Other indication schemes may be available to one of ordinary skill in the art without departing from the scope of the present disclosure.

In some embodiments, table 200 may also include programmed value column 208. Programmed value column 208 may include the value to be written into the specified data by, for example, OTP controller 102. For example, in the first row, table 200 indicates that the value “0000” should be written to the data value. This is because the zero bias is less than fifty percent (as indicated in the first row of zero bias column 204), and thus no inversion has taken place (as indicated in the first row of inversion indication column 206). Other example values are illustrated in FIG. 2.

Thus is disclosed a system and method for minimizing OTP programming time algorithmically selecting between inverted and non-inverted programming Words. In order to put a maximum value to the programming time for the entire array, it is possible to introduce a limiting of the number of bits being programmed to ‘1’, and therefore a limiting of the total programming time. This is done at the cost of adding one extra OTP bit for each n-bit word (where n bits represents the read/write width of the OTP array). For example, a 32-bit wide OTP array would be updated to be 33 bits wide.

What is claimed is:

1. A circuit arrangement for programming a one-time programmable (OTP) memory, comprising:
an OTP memory array comprising an array organized in lines of n+1 bit, wherein n is an integer number designating a word size of the OTP memory, wherein the additional bit indicates whether a memory line is stored in an inverted or non-inverted fashion;
encoding logic configured determine whether a word is to be stored inverted or non-inverted; and
decoding logic configured to decode a stored word and controlled by the additional bit indicating whether a word has been stored inverted or non-inverted.

2. The circuit arrangement according to claim 1, wherein the encoding logic stores a word inverted if the number of bit having a value of ‘1’ is greater than n/2 and setting the additional bit in that word and if not then the encoding logic stores a word non-inverted without setting the additional bit.

3. The circuit arrangement according to claim 2, wherein the encoding logic comprises an inverter for inverting a word to be stored in the OTP memory, a multiplexer receiving the word and the inverted word, and a counter configured to count the number of logic ‘1’ in the word and operable to control the multiplexer to select the inverted word if the number of logic 1′ in the word is greater than n/2 and otherwise select the word for storage in the OTP memory.

4. The circuit arrangement according to claim 1, wherein the decoding logic comprises an inverter configured to invert a stored n-bit word and a multiplexer receiving the stored word and the inverted word, wherein the multiplexer is controlled by the additional bit.

5. The circuit arrangement according to claim 1, wherein n=32.

6. The circuit arrangement according to claim 1, wherein the OTP memory comprises address and control inputs for reading and writing a word.

7. The circuit arrangement according to claim 1, wherein the encoding logic stores a word inverted if the number of bit having a value of ‘1’ is greater than Or equal to n/2 and setting the additional bit in that word and if not then the encoding logic stores a word non-inverted without setting the additional bit.

8. The circuit arrangement according to claim 1, wherein the encoding logic stores a word inverted if the number of bit having a value of ‘1’ is greater than an inversion threshold and setting the additional bit in that word and if not then the encoding logic stores a word non-inverted without setting the additional bit.

9. A method for programming a one-time programmable (OTP) memory, the method comprising:
storing a data word in an OTP memory array comprising an array organized in lines of n+1 bit, wherein n is an integer number designating the data word size of the OTP memory, wherein the additional bit indicates whether a memory line is stored in an inverted or non-inverted fashion;
determining whether a word is to be stored inverted or non-inverted; and
decoding a stored word and controlled by the additional bit indicating whether a word has been stored inverted or non-inverted.

10. The method according to claim 9, wherein storing the data word inverted comprises storing the data word inverted if the number of bit having a value of ‘1’ is greater than n/2 and setting the additional bit in that word and if not then the encoding logic stores a word non-inverted without setting the additional bit.

11. The method according to claim 10, wherein storing the data word comprises storing the data word via encoding logic, wherein the encoding logic comprises an inverter for inverting a word to be stored in the OTP memory, a multiplexer receiving the word and the inverted word, and a counter configured to count the number of logic ‘1’ in the word and operable to control the multiplexer to select the inverted word if the number of logic ‘1’ in the word is greater than n/2 and otherwise select the word for storage in the OTP memory.

12. The method according to claim 1, wherein decoding the stored word comprises decoding the stored word via decoding logic, and wherein the decoding logic comprises an inverter configured to invert a stored n-bit word and a multiplexer receiving the stored word and the inverted word, wherein the multiplexer is controlled by the additional bit.

13. The method according to claim 1, wherein n=32.

14. The method according to claim 1, wherein the OTP memory comprises address and control inputs for reading and writing a word.

15. A computer-implemented method for executing program instructions stored on non-transitory computer-readable media by a processor, wherein the instructions when executed by the processor perform the steps comprising:
storing a data word in an OTP memory array comprising an array organized in lines of n+1 bit, wherein n is an integer number designating the data word size of the OTP memory, wherein the additional bit indicates whether a memory line is stored in an inverted or non-inverted fashion;
determining whether a word is to be stored inverted or non-inverted; and
decoding a stored word and controlled by the additional bit indicating whether a word has been stored inverted or non-inverted.

16. The computer-implemented method according to claim 15, wherein storing the data word inverted comprises storing the data word inverted if the number of bit having a value of ‘1’ is greater than n/2 and setting the additional bit in that word and if not then the encoding logic stores a word non-inverted without setting the additional bit.

17. The computer-implemented method according to claim 16, wherein storing the data word comprises storing the data word via encoding logic, wherein the encoding logic comprises an inverter for inverting a word to be stored in the OTP memory, a multiplexer receiving the word and the inverted word, and a counter configured to count the number of logic ‘1’ in the word and operable to control the multiplexer to select the inverted word if the number of logic ‘1’ in the word is greater than n/2 and otherwise select the word for storage in the OTP memory.

18. The computer-implemented method according to claim 15, wherein decoding the stored word comprises decoding the stored word via decoding logic, and wherein the decoding logic comprises an inverter configured to invert a stored n-bit word and a multiplexer receiving the stored word and the inverted word, wherein the multiplexer is controlled by the additional bit.

19. The computer-implemented method according to claim 15, wherein n=32.

20. The computer-implemented method according to claim 15, wherein the OTP memory comprises address and control inputs for reading and writing a word.
